(19) United States
(12) Patent Application Publication
(10) Pub. No.: US 2019/0203377 A1
(43) Pub. Date: Jul. 4, 2019

(54) SYNTHETIC LINED CRUCIBLE ASSEMBLY FOR CZOCHRALSKI CRYSTAL GROWTH

(71) Applicant: Corner Star Limited, Kowloon (HK)

(72) Inventors: Arash Mehdizadeh Dehkordi, St. Charles, MO (US); Joseph Conrad Holzer, St. Peters, MO (US)

(21) Appl. No.: 16/229,718

(22) Filed: Dec. 21, 2018

Related U.S. Application Data
(60) Provisional application No. 62/611,758, filed on Dec. 29, 2017.

(51) Int. Cl. C30B 15/10; C30B 15/14; C30B 15/00; C04B 41/00; C04B 41/50; C04B 41/87; B05B 7/22

(52) U.S. Cl. CPC C30B 15/10; C30B 15/14; C30B 15/007; B05B 7/226; C04B 41/5035; C04B 41/87; C04B 41/009

(57) ABSTRACT

A method of manufacturing a crucible assembly having a shell and a liner is disclosed. The method includes forming the shell using a casting process. The shell includes silica and has an inner surface and an outer surface. The method also includes forming the liner on the inner surface of the shell. The liner is formed of synthetic silica.

### CROSS-REFERENCE TO RELATED APPLICATION

This application claims the benefit of U.S. Provisional Patent Application No. 62/611,758, filed Dec. 29, 2017, which is incorporated herein by reference in its entirety.

### FIELD

This disclosure relates generally to systems and methods for producing ingots of solar-grade or semiconductor material and, more particularly, to crucible assemblies including a synthetic lining for use in such systems and methods.

### BACKGROUND

Crystalline silicon solar cells currently contribute the majority of the total supply of the photovoltaic (PV) modules. In the standard Czochralski (CZ) method, polycrystalline silicon is first melted in a crucible, such as a quartz crucible, to form a silicon melt. A seed crystal of predetermined orientation is then lowered into contact with the melt and is slowly withdrawn. By controlling the temperature, silicon melt at the seed-melt interface solidifies onto the seed crystal with the same orientation as that of the seed. The seed is then slowly raised from the melt to form a growing crystal ingot. In the conventional CZ process, called batch CZ (BCZ), the entire amount of charge material needed for growing a silicon ingot is melted at the beginning of the process, a crystal is pulled from a single crucible charge to substantially deplete the crucible, and the quartz crucible is then discarded. Another method to economically replenish a quartz crucible for multiple pulls in one furnace cycle is continuous CZ (CCZ). In CCZ, the solid or liquid feedstock is continuously or periodically added to the melt as the crystal is grown and therefore maintains the melt at a constant volume. In addition to spreading the crucible cost across several ingots, the CCZ method provides superior crystal uniformity along the growth direction.

Cast silica crucibles, formed of lower grade natural silica, are generally not used in Czochralski based methods (CZ, BCZ, and CCZ methods) because the lower grade natural silica has a high total impurity level. Rather, cast crucibles, or multi-silica cast crucibles, are typically used in the manufacture of multi-crystalline silica photovoltaic cells because of the higher total impurity level. The higher total impurity level of the lower grade natural silica comes from naturally occurring impurities in the silica and from impurities added to the silica during the casting process to bind the silica into a cast crucible form. The higher total impurity level of cast crucibles increases impurity contributions from the crucible into the melt, and into the end product.

In contrast, crucibles used in Czochralski based methods (such as arc-fused crucibles) are formed of higher grade, more expensive natural silica which have a lower total impurity level compared to cast crucibles formed of lower grade natural silica. Ingots formed from these crucibles have lower impurity levels than ingots form from cast crucibles. Thus, there exists a need for a lower cost crucible for use in Czochralski based methods that reduces the impurity contribution from the crucible.

Additionally, known crucibles for use in Czochralski based methods suffer from limited design flexibility, and have limited crucible lifetimes. Thus, there exists a need for a crucible for use Czochralski based methods that has improved design flexibility and improved crucible lifetime, e.g., to extend the length of a furnace cycle.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF SUMMARY

A first aspect is a method of manufacturing a crucible assembly having a shell and a liner. The method includes forming the shell using a casting process. The shell includes silica and has an inner surface and an outer surface. The method also includes forming the liner on the inner surface of the shell. The liner formed of synthetic silica.

Another aspect is a crucible assembly for growing a crystal ingot using a Czochralski process. The crucible assembly includes a shell and a liner. The shell is formed of silica and has an inner surface and an outer surface opposite the inner surface. The liner is formed of synthetic silica and is formed on the inner surface of the shell. The liner is a thermal sprayed liner and the shell is a cast shell.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a sectional view of a crucible assembly including a body and a liner.

FIG. 2 is a flow chart illustrating one suitable method for making the shell shown in FIG. 1.

FIG. 3 is a block diagram of a thermal spray assembly.

FIGS. 4A-4B are flow charts illustrating one suitable method for using the thermal spray assembly shown in FIG. 3.

FIG. 5 is a flow chart illustrating one suitable method for making the crucible assembly shown in FIG. 1.

FIG. 6 is a flow chart illustrating one suitable method for pulling a crystal ingot using the Czochralski method and the crucible assembly shown in FIG. 1.

FIG. 7 is a sectional view of another crucible assembly including a body and a liner.

Corresponding reference characters indicate corresponding parts throughout the several views of the drawings.

### DETAILED DESCRIPTION

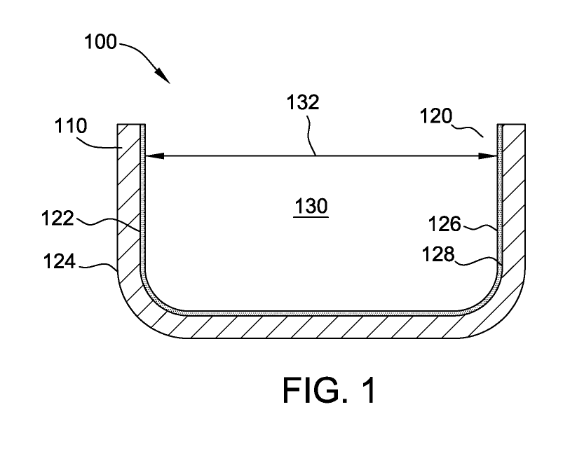

Referring now to FIG. 1, a crucible assembly 100 of one example embodiment includes a shell 110 and a liner 120 positioned within shell 110 such that only liner 120 contacts the melt. Shell 110 is made of a relatively lower grade natural silica using a casting process and liner 120 is made of a relatively higher grade natural or synthetic silica using a thermal spray process. Higher grade natural or synthetic silica contributes less impurities to the melt than lower grade natural silica and is more expensive than lower grade natural silica. In comparison to a crucible assembly formed completely of the higher grade natural or synthetic silica, this provides for a reduced overall cost of crucible assembly 100 while maintaining and/or improving the quality of the melt.

In the example crucible assembly 100, shell 110 has an inner surface 122 and an outer surface 124 and liner 120 also has an inner surface 126 and an outer surface 128. Liner 120 is formed on inner surface 122 of shell 110 such that outer surface 128 of liner 120 conforms to inner surface 122 of shell 110. Liner 120 is made from ultra-high purity natural sand or synthetic quartz while the remainder of the crucible assembly 100 including shell 110 and outer surface 124 is made from lower purity materials. Melt material is melted within a growth region 130 defined by liner 120 and only contacts inner surface 126 of liner 120. As such, liner 120 prevents the melt from contacting the lower purity materials within shell 110 and increases the quality of the melt.

Shell 110 and liner 120 are bowl shaped and liner 120 is thermally sprayed within shell 110. Crucible assembly 100 has a diameter 132 extending between inner surface 126 of liner 120. In some embodiments, diameter 132 is at least twenty inches, less than forty inches, between twenty four inches and thirty two inches, between twenty eight inches and thirty four inches, or between thirty inches and thirty six inches.

Crucible assembly 100 illustrated in FIG. 1 is formed by first forming shell 110 by a casting process or a non-casting process. Then liner 120 is formed on inner surface 122 of shell 110 by a thermal spray process. Casting processes include a slip casting process and a gel casting process and non-casting processes include an arc-fusion process. In the present embodiment, shell 110 is formed from the slip casting process. However, in alternative embodiments, shell 110 may be formed from the gel casting process or the arc-fusion process.

In the illustrated embodiment, shell 110 is suitably a slip cast shell, but may be another type of cast shell or crucible. Casting processes suitable for forming cast crucibles generally include pouring a liquid or semi-liquid compound into a mold, and allowing the compound to solidify by removing moisture from the compound. The compounds used to form cast shell 110 may include, for example and without limitation, an aqueous slurry of ceramic powder, such as silica powder. Suitable casting processes for forming cast crucibles include, for example and without limitation, slip casting and gel casting. Slip casting includes the use of aqueous slurry of ceramic powder, e.g., silica, known as slip. The ceramic powder may be mixed with dispersing agents, binders, water, and/or other components. The slip and/or slip mixture, e.g., slurry, is poured into a mold. For example, the mold is suitably made of plaster of Paris, e.g., CaSO₄:2H₂O. The water from the slurry begins to move out by capillary action (or with the help of vacuum drying), and a mass builds along the mold wall. When the desired thickness of the dried mass is reached, the rest of the slurry is poured out of the mold. The green ceramic is then removed from the mold, dried, and fired. The firing process includes sintering, or fusing in the case of silica, at high temperature. The end product is opaque at room temperature but can be transparent depending on the sintering condition and temperature.

In an alternative embodiment, shell 110 is made using a gel casting process or other casting process. In a gel casting process, ceramic powder, e.g., natural sand, synthetic quartz, or SiO₂, is milled and/or mixed with water, a dispersant, and gel-forming organic monomers. The mixture is placed under partial vacuum to remove air from the mixture. This increases the rate of drying and/or reduces the formation of bubbles in the gel cast product. A catalyst, e.g., a polymerization initiator, is added to the mixture. The polymerization initiator begins a gel-forming chemical reaction within the mixture. The slurry mixture is cast by pouring the mixture into a mold of the desired shape for creating the product, e.g., a crucible. The mold may be made of, for example, metal, glass, plastic, wax, or other materials. A gel is created from the slurry mixture by heating the molds and slurry mixture in a curing oven. The heat and catalyst cause the monomers in the mixture to form cross-linked polymers which trap water in the mixture to great a polymer-water gel. The gel binds and immobilizes the ceramic particles within the gel. The ceramic is removed from the mold. The ceramic is dried. The dried ceramic may be machined to further shape the ceramic. The ceramic is fired to burn out the polymer within the ceramic and sinter the ceramic particles. In further alternative embodiments, other casting, machining, or production processes are used to make shell 110.

In another alternative embodiment, shell 110 is formed by a non-casting process. For example, shell 110 is formed using an arc-fusion process. The process generally includes fusing a precursor material (e.g., high purity quartz sand) with an electrical arc. In one embodiment, shell 110 is formed by pouring high purity quartz sand into a rotating mold, and then fusing from the inside out using an arc generated by two or more graphite electrodes. High purity quartz sand is defined as sand which contains no more than 30 parts per million by weight (ppmw) of impurities. The industry standard for high purity quartz is defined by a product marketed as IOTA mined by Unimin Corporation at Spruce Pine, N.C., US, which serves as the high-purity benchmark for the high-purity quartz market. In this embodiment, the high purity quartz sand has a total impurity level not exceeding 20 ppmw. The mold may include vacuum holes through which air trapped between the sand particles, as well as the gaseous species generated during the fusion process, are removed in order to avoid the formation of bubbles in the final as-fused crucible. The resulting arc-fused crucible is substantially transparent or semi-transparent, depending on the bubble density, at room temperature.

In the present embodiment, shell 110 is formed using the slip casting process, or another type of casting process, to reduce the cost of the crucibles in comparison to arc-fused crucibles. The slip casting process, or other type of casting process, provides for less costly design changes (and increases design flexibility) to shell 110 in comparison to the arc-fusion process because crucibles manufactured using the slip casting process are made from cheaper, lower grade natural silica rather than more expensive, higher grade natural or synthetic silica. Additionally, the slip cast manufacturing process is cheaper than the arc-fused manufacturing process because the arc-fused manufacturing process has a significantly higher operating temperature than the slip cast manufacturing process and requires specialized equipment to achieve the higher operating temperature. Therefore, using a slip cast, or otherwise cast, crucible as shell 110 in crucible assembly 100 reduces the cost of crucible assembly 100.

Shell 110 formed using the slip casting process, or other casting process, can have a density of greater than ninety to ninety five percent of the maximum theoretical density for silica slip cast crucibles. Shell 110 formed by the slip cast process and made of silica possesses similar thermal shock resistance properties to that of crucibles formed of other processes, such as amorphous arc-fused crucibles. Cast crucibles of this embodiment are opaque at room temperature, in contrast to other types of crucibles, such as arc-fused crucibles or thermal sprayed crucibles, that are typically transparent or semi-transparent. Note that cast crucibles of other embodiments may be transparent, e.g., depending on sintering conditions used in firing the cast crucible. In comparison to other types of crucibles, such as arc-fused crucibles, cast crucibles typically require additional input power and time to melt material contained therein, due to reduced infrared transmission through the opaque cast crucible in comparison to transparent or semi-transparent arc-fused crucibles. However, the decrease in infrared transmission of cast crucibles may result in less radiative heat loss from the melt after the melt down in comparison to arc-fused crucibles. As a result, a cast crucible might not vary in overall power consumption throughout a run compared to arc-fused crucibles. Cast crucibles have a dissolution rate lower than the dissolution rate of arc-fused crucibles.

Additionally, slip cast crucibles typically have higher levels of impurities in comparison to thermal spray liners. The high impurity content of cast crucibles can originate from ball milling media used to pulverize fused silica feedstock, impurities in the mold material used to create the cast crucible, and the binder and dispersing agent. Slip cast crucibles include a wall of substantially uniform material that is formed of lower grade natural silica, which includes higher levels of impurities. This is in contrast to a thermal spray liner made from ultra-high purity natural sand or synthetic quartz which typically have substantially lower levels of impurities than slip cast crucibles.

Shell 110, in general, includes greater amounts of impurities than thermally sprayed liners. This is a result of the slip cast process, or other casting process, used to make the crucible. In alternative embodiments, shell 110, formed by a slip cast process or other casting process, has a low amount of impurities. For example, shell 110 has 20 parts per million, by weight, or less of impurities. Impurities, such as aluminum, have a significant impact on low-injection minority carrier lifetime in crystals and lower the efficiency of solar cells made from the crystals. A high purity cast shell 110 reduces impurities and results in more efficient solar cells.

Cast silica crucibles formed of lower grade natural silica, such as shell 110, are generally not used in Czochralski based methods because lower grade natural silica has a high total impurity level. Low grade natural silica is typically mined and has 99% by weight silica with 1% by weight impurities. Cast crucibles, or multi-silica cast crucibles, are typically used in the manufacture of multi-crystalline silica photovoltaic cells because of the higher total impurity level. The higher total impurity level comes from naturally occurring impurities and from impurities added to the silica during the casting process to bind the silica into a cast crucible form. The higher total impurity level of the natural silica increases impurity contribution from the crucible into the melt, and into the end product. Cast crucibles, or multi-silica cast crucibles, are typically opaque and have a square bottom. In contrast, higher grade natural silica is typically refined lower grade natural silica with an impurity level low enough such that it can be used to form crucibles used in Czochralski based methods. Crucibles made from higher grade natural or synthetic silica and used in Czochralski based methods are typically semi-transparent or transparent and have a bowl shaped bottom.

In some embodiments, cast shell 110 has an impurity content greater than 50 ppmw, greater than 100 ppmw, greater than 200 ppmw, between 50 ppmw and 1,000 ppmw, between 50 ppmw and 500 ppmw, between 100 ppmw and 1,000 ppmw, between 100 ppmw and 500 ppmw, between 100 ppmw and 400 ppmw, between 200 ppmw and 300 ppmw, greater than 1000 ppmw, or other impurity content greater than that of a thermally sprayed liner made from ultra-high purity natural sand or synthetic quartz (e.g., having an impurity content of less than 0.13 ppmw). Examples of impurities that are measured or accounted for in the total impurity content of shell 110 include, for example, Al, B, Ba, Ca, Cr, Cu, Fe, K, Li, Mg, Mn, Na, Ni, P, Ti, Zn, and Zr. For example, shell 110 may have a total impurity content of less than 230 ppmw with the following specific impurity contents: 100 ppmw Al, 1 ppmw B, 10 ppmw Ba, 20 ppmw Ca, less than 1 ppmw Cu, 20 ppmw Fe, 15 ppmw K, 10 ppmw Li, 9 ppmw Mg, 23 ppmw Mn, 10 ppmw Na, 10 ppmw Ti, and less than 1 ppmw Zr.

In comparison, liners formed of thermally sprayed higher grade natural or synthetic silica of the present disclosure may have an impurity content less than that of slip cast shell 110, such as less than 50 ppmw, less than 30 ppmw, less than 20 ppmw, less than 15 ppmw, less than 10 ppmw, less than 1 ppmw, less than 0.5 ppmw, between 0.01 ppmw and 50 ppmw, between 0.01 ppmw and 30 ppmw, between 0.01 ppmw and 20 ppmw, between 5 ppmw and 50 ppmw, between 10 ppmw and 30 ppmw, or other impurity content less than that of a slip cast crucible. For example, a higher grade natural or synthetic silica liner may have a total impurity content of less than 5 ppmw, less than 4 ppmw, less than 3 ppmw, less than 2 ppmw, less than 1 ppmw, or less than 0.13 ppmw with the following specific impurity contents: 0.01 ppmw Al, less than 0.01 ppmw B, 0.01 ppmw Ca, 0.01 ppmw Cr, 0.01 ppmw Cu, 0.02 ppmw Fe, 0.01 ppmw K, 0.01 ppmw Li, 0.01 ppmw Mg, 0.01 ppmw Mn, 0.01 ppmw Na, 0.01 ppmw Ni, less than 0.01 ppmw P, 0.01 ppmw Ti, and 0.01 ppmw Zn. In other embodiments, thermally sprayed liners have various total impurity contents, various specific impurity contents, and/or other types of impurities.

The crystal ingot generated by the Czochralski process is pulled from growth region 130. Growth region 130 extends within inner surface 126 of liner 120. In operation, the melt contained within liner 120 and shell 110 gradually dissolves inner surface 126 of liner 120. This dissolution reaction introduces material from inner surface 126 of liner 120 into the melt and introduces impurities into the melt. However, because liner 120 is formed of higher grade natural or synthetic silica, substantially no impurities are introduced from inner surface 126 of liner 120. Crucible assembly 100 generates a higher purity crystal ingot by preventing at least some impurities from entering growth region 130 and by preventing those impurities from being incorporated into the crystal ingot. Crucible assembly 100 benefits from the increased design flexibility, reduced cost, and increased crucible lifetime afforded by cast shell 110 while reducing the impact of impurities in cast shell 110.

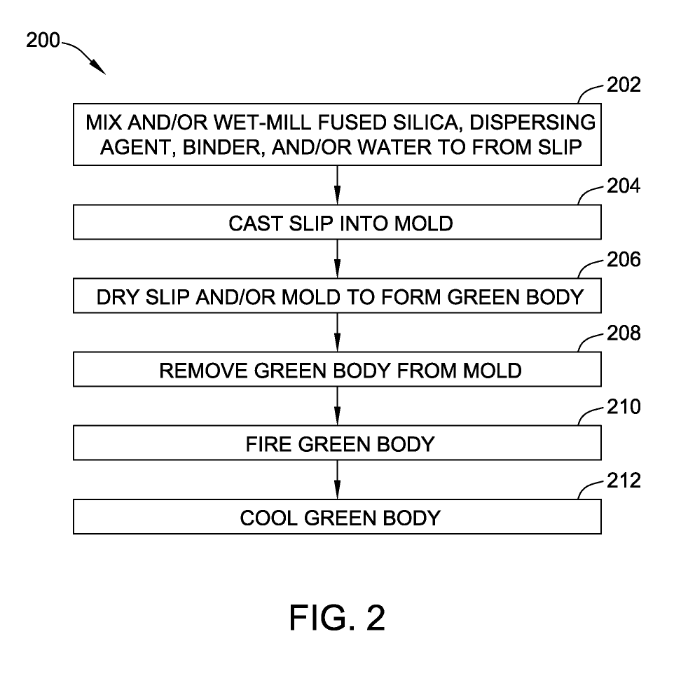

Referring now to FIG. 2, a flow chart illustrates an example method 200 for making, using a slip casting process, a crucible for use in the crucible assembly 100 shown in FIG. 1. This and/or other processes are used to make shell 110. The method 200 generally includes mixing 202 silica and other components to form a slip, casting 204 the slip into a mold, drying 206 the slip and/or mold to form a green body, removing 208 the green body from the mold, firing 210 the green body, and cooling 212 the green body.

The step of mixing 202 silica and other components to form slip includes mixing silica with dispersing agent, binder, and/or water to form slip. The silica which is mixed may be fused silica which is wet-milled. Casting 204 the slip into the mold includes pouring the slip mixture into the mold. The mold is typically made of plaster of Paris. In embodiments where gel casting is used rather than slip casting, the mold is, for example, stainless steel. The step of drying 206 the slip and/or mold to form the green body includes water moving out of the slurry through capillary action with or without assistance from vacuum drying. A green body is an unfired shaped powder form. During the drying of the slip, dried mass forms along the mold wall. When the desired thickness of the dried mass is reached, the remaining liquid slurry is poured out. Firing 210 the green body includes sintering or fusing the dried mass, e.g., the silica within the dried mass, at high temperature.

Liner 120 is thermal sprayed liner formed by a thermal spray process. The process generally includes spraying a liquid or semi-liquid compound onto shell 110, and allowing the compound to solidify on inner surface 122 of shell 110. In one embodiment, liner 120 is formed by melting higher grade natural or synthetic silica or high purity quartz sand and spraying the melted higher grade natural or synthetic silica on inner surface 122 of shell 110. High purity quartz sand is defined as sand which contains no more than 30 ppmw of impurities. The industry standard for high purity quartz is defined by a product marketed as IOTA mined by Unimin Corporation at Spruce Pine, N.C., US, which serves as the high-purity benchmark for the high-purity quartz market. In this embodiment, the higher grade natural or synthetic silica or synthetic quartz has a total impurity level not exceeding 0.13 ppmw. In some embodiments, the higher grade natural or synthetic silica or synthetic quartz has a total impurity level less than 5 ppmw, less than 4 ppmw, less than 3 ppmw, less than 2 ppmw, less than 1 ppmw, or less than or equal to 0.13 ppmw.

In batch or recharge Czochralski processes, ultra-high purity natural sand or synthetic quartz, e.g., SiO₂, may be used for liner 120, which is in contact with molten silicon within growth region 130, whereas shell 110 is made of lower purity sand. This configuration may also be used for continuous Czochralski processes. Ultra-high purity natural sand has a higher purity than high purity natural sand, such as no more than 0.13 ppmw. Synthetic quartz has a higher purity than ultra-high purity natural sand, such as no more than 0.13 ppmw.

In alternative embodiments, both liner 120 and shell 110 may be formed from ultra-high purity natural sand or synthetic quartz. In yet further alternative embodiments, the entire crucible assembly 100 is made from a single material or predominantly a single material. For example, crucible assembly 100 may be made entirely of ultra-high purity natural sand or synthetic quartz having less than 20 parts per million impurities by weight.

As described herein, the thermal spray process generically describes many processes broadly categorized into three thermal spray process categories: flame thermal spray processes, electrical thermal spray processes, and kinetic thermal spray processes. Each category of thermal spray process melts or propels the coating compound in a unique manner. For example, flame thermal spray processes typically melt the coating compound with a flame while electrical thermal spray processes uses electrical currents to melt the coating compound. Kinetic thermal spray processes typically propel the coating compound at an extremely high velocity such that the compound deforms and bonds on impact. All thermal spray processes generally require a spray torch, a coating compound, and energy to melt or propel the coating compound.

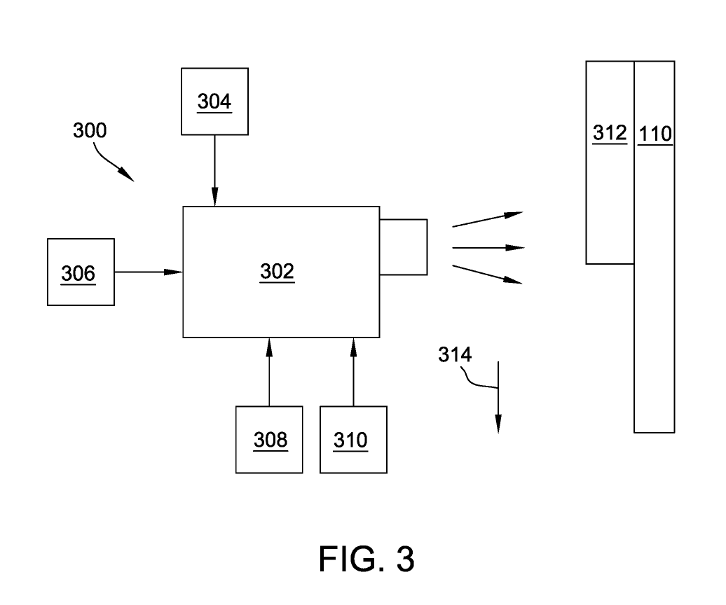

Referring now to FIG. 3, a block diagram of a thermal spray assembly 300 useful for all thermal spray processes is illustrated. Thermal spray assembly 300 generally includes a spray torch or spray gun 302, a source of energy 304, a source of coating compound 306, a source of acceleration media 308, and, optionally, a source of a cooling medium 310. Source of coating compound 306 provides a coating compound to spray gun 302. In this embodiment, the coating compound is higher grade natural or synthetic silica. In alternative embodiments, the coating compound is ultra-high purity natural sand, high purity natural sand, or any coating compound that enables crucible assembly 100 to operate as described herein. Source of energy 304 provides energy to melt the coating compound into molten particles before the coating compound is sprayed onto shell 110. Source of acceleration media 308 provides a suitable media for accelerating the molten particles of the coating compound toward shell 110. In some embodiments, source of energy 304 and source of acceleration media 308 are combined into a single source of energy and acceleration media. In some embodiments, source of cooling medium 310 provides a cooling medium, generally water, to cool spray gun 302 during operations.

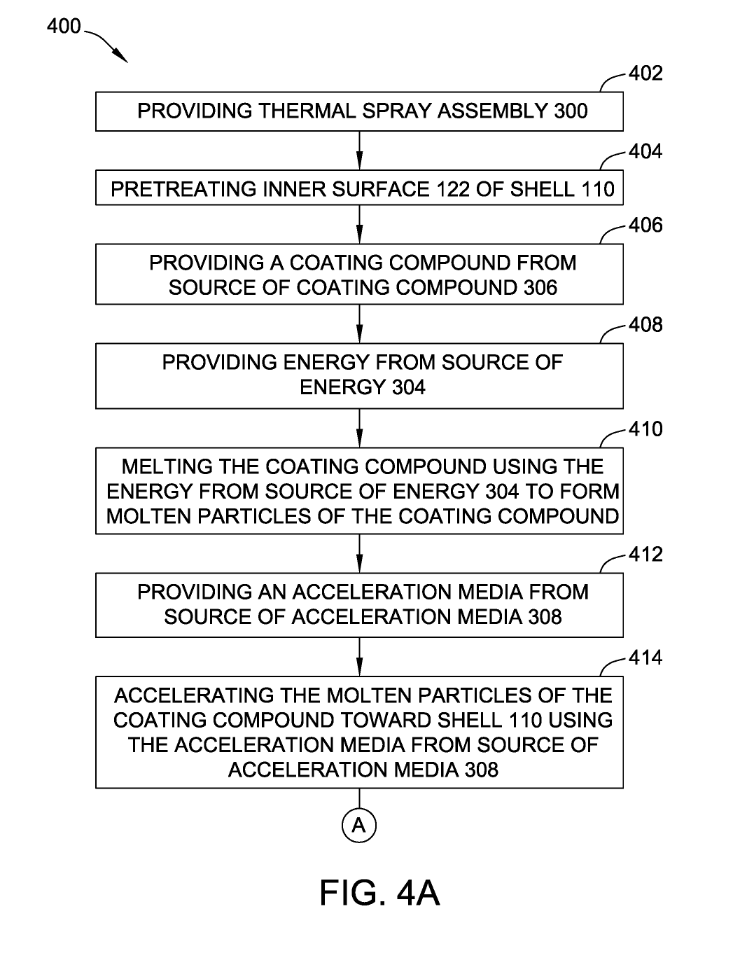

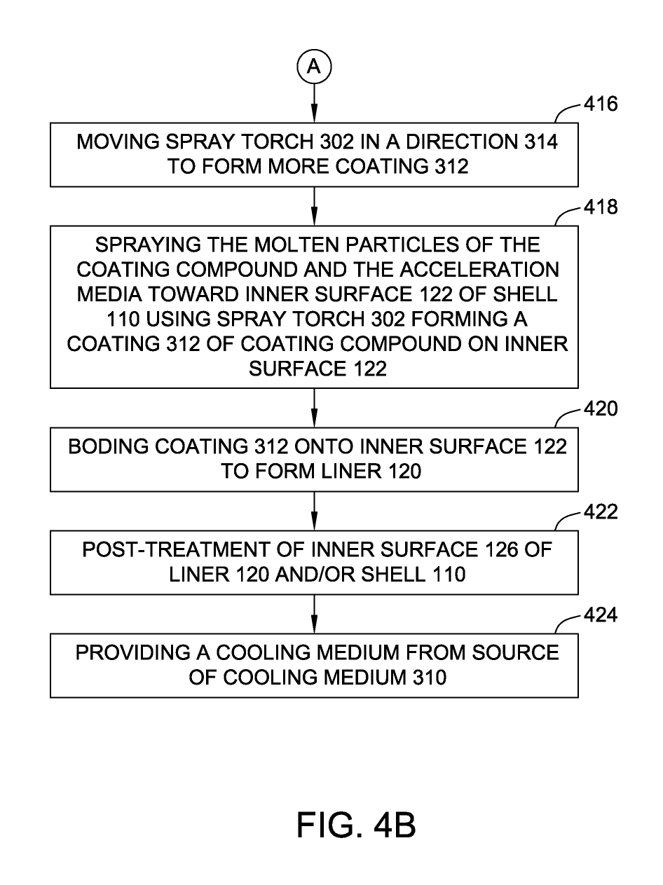

Referring now to FIG. 4, a flow chart illustrates method 400 for thermally spraying liner 120 onto shell 110. The method 400 generally includes providing 402 thermal spray assembly 300, pretreating 404 inner surface 122 of shell 110, providing 406 a coating compound from source of coating compound 306, providing 408 energy from source of energy 304, melting 410 the coating compound using the energy from source of energy 304 to form molten particles of the coating compound, providing 412 an acceleration media from source of acceleration media 308, accelerating 414 the molten particles of the coating compound toward shell 110 using the acceleration media from source of acceleration media 308, spraying 416 the molten particles of the coating compound and the acceleration media toward inner surface 122 of shell 110 using spray torch 302 forming a coating 312 of coating compound on inner surface 122, moving 418 spray torch 302 in a direction 314 to form more coating 312, boding 420 coating 312 onto inner surface 122 to form liner 120, and post-treating 422 inner surface 126 of liner 120 and/or shell 110 with or without a plasma jet. Method 400 may also optionally include providing 424 a cooling medium from source of cooling medium 310. Providing 402 thermal spray assembly 200 generally includes providing spray torch 302, source of energy 304, source of coating compound 306, source of acceleration media 308, and source of cooling medium 310. Providing 404 a coating compound from source of coating compound 306 includes providing higher grade natural or synthetic silica.

Pretreating 404 inner surface 122 of shell 110 is a pretreatment process which may improve bonding, deposition, and/or spraying of liner 120 to shell 110 and/or the quality of liner 120. Pretreating 404 may include preheating inner surface 122 of shell 110, chemically pretreating inner surface 122 of shell 110, a roughness pretreatment on inner surface 122 of shell 110, and/or any process that improves the adhesion of liner 120 to shell 110. Any of the pretreatment processes listed above may be used alone or in combination with any other pretreatment process.

The preheating pretreatment process generally includes preheating inner surface 122 of shell 110 prior to thermally spraying liner 120 onto shell 110. A preheating device, such as a furnace or a blow torch, may be used to preheat inner surface 122 of shell 110. Additionally, thermal spray assembly 300 may be used to preheat inner surface 122 of shell 110 when a flame thermal spray process is used to thermally spray liner 120. Specifically, thermal spray assembly 300 may pre-spray inner surface 122 of shell 110 without any coating compound such that the flame normally used to melt the coating compound is instead used to preheat inner surface 122 of shell 110. The preheating process may include any process or device that preheats inner surface 122 of shell 110 to improve the adhesion of liner 120 to shell 110.

The chemical pretreatment process generally includes chemically pretreating inner surface 122 of shell 110 prior to thermally spraying liner 120 onto shell 110. A chemical pretreatment device, such as a spray device or other chemical application device, may be used to pretreat inner surface 122 of shell 110. Additionally, thermal spray assembly 300 may be used to chemically pretreat inner surface 122 of shell 110. Specifically, thermal spray assembly 300 may be used to spray a pretreatment coating that improves the adhesion of liner 120 to shell 110. The pretreatment coating may include a paste or a solvent that improves the adhesion of liner 120 onto shell 110. The chemical pretreatment process may include any process or device that pretreats shell 110 to improve the adhesion of liner 120 to shell 110.

The roughness pretreatment process generally includes mechanically altering the roughness inner surface 122 of shell 110 prior to thermally spraying liner 120 onto shell 110. A roughness pretreatment device, such as a sanding device or other mechanical surface treatment device, may be used to pretreat inner surface 122 of shell 110. The mechanical surface treatment device may be used to increase or decrease the roughness of inner surface 122 of shell 110 to improve the adhesion of liner 120 to shell 110. The roughness pretreatment process may include any process or device that pretreats shell 110 to improve the adhesion of liner 120 to shell 110.

After liner 120 has been thermally sprayed onto shell 110, liner 120 cools and solidifies to form a glassy silica layer. To ensure that a glassy, amorphous silica layer is formed, the cooling and solidifying process is controlled or optimized. Specifically, post-treating 422 inner surface 126 of liner 120 and/or shell 110 is an optional post-treatment process that controls or optimizes the cooling and/or solidifying process. Post-treating 422 may include a cooling rate post-treatment process, a chemical post-treatment process, a plasma jet post-treatment process, and/or any process that improves the adhesion of liner 120 to shell 110. Any of the post-treatment processes listed above may be used alone or in combination with any other post-treatment process.

The cooling post-treatment process generally includes controlling or optimizing the cooling rate of liner 120 and/or shell 110 to improve the adhesion of linter 120 onto shell 110. The post-treatment cooling process may include cooling liner 120 and/or shell 110 using a cooling device, such as a fan or blower, to increase the cooling rate of liner 120 and/or shell 110 to improve the adhesion of liner 120 to shell 110. The post-treatment cooling process may also include cooling liner 120 and/or shell 110 by directing a low temperature gas toward inner surface 126 of liner 120 to increase the cooling rate of liner 120 and/or shell 110 to improve the adhesion of liner 120 to shell 110. The post-treatment cooling process may also include heating liner 120 and/or shell 110 using a heating device, such as a furnace or a blow torch, to decrease the cooling rate of liner 120 and/or shell 110 to improve the adhesion of liner 120 to shell 110. The post-treatment cooling process may include any process or device that controls, optimizes, increases, and/or decreases the cooling rate of liner 120 and/or shell 110 to improve bonding, deposition, and/or spraying of liner 120 to shell 110 and/or the quality of liner 120.

The chemical post-treatment process generally includes chemically post-treating liner 120 and/or shell 110 after thermally spraying liner 120 onto shell 110. A chemical post-treatment device, such as a spray device or other chemical application device, may be used to chemically post-treat liner 120 and/or shell 110. Additionally, thermal spray assembly 300 may be used to chemically post-treat liner 120 and/or shell 110. Specifically, thermal spray assembly 300 may be used to spray a post-treatment coating on liner 120 and/or shell 110 that improves the adhesion of liner 120 to shell 110. The post-treatment coating may include a paste or a solvent that improves the adhesion of liner 120 onto shell 110. The chemical post-treatment process may include any process or device that post-treats shell 110 to improve the adhesion of liner 120 to shell 110.

The thermal post-treatment process generally includes thermally treating inner surface 126 of liner 120 after thermally spraying liner 120 onto shell 110. A thermal treatment device, such as a plasma torch, may be used to thermally treat inner surface 126 of liner 120. Additionally, thermal spray assembly 300 may be used to thermally treat inner surface 126 of liner 120 when a plasma spray process is used to thermally spray liner 120. Specifically, thermal spray assembly 300 may spray inner surface 126 of liner 120 without any coating compound such that the plasma jet normally used to melt the coating compound is instead used to thermally treat inner surface 126 of liner 120. The thermal post-treatment process may include any process or device that thermally treats inner surface 122 of shell 110 to improve the adhesion of liner 120 to shell 110.

Additionally, any of the post-treatment processes listed above may be used in combination with any other post-treatment process to ensure that liner 120 forms into an amorphous glass rather than a crystalline glass. Specifically, if the temperature of thermally sprayed liner 120 is too high, and the cooling rate is too low, liner 120 will form a crystalline glass liner 120 rather than an amorphous glass liner 120. As such, a combination of post-treatment processes may be used to control the cooling rate of liner 120. For example, at the end of the thermal spraying process a thermal post-treatment process may be used to maintain the high temperature of liner 120 until a cooling post-treatment process is initiated to control the cooling rate of liner 120. Specifically, thermal spray assembly 300 may spray inner surface 126 of liner 120 with a plasma jet to maintain the temperature of liner 120 immediately after liner 120 has been thermally sprayed onto shell 110. Thermal spray assembly 300 maintains the temperature of liner 120 until a cooling post-treatment process is initiated to control the cooling rate of liner 120. The cooling post-treatment process may include a cooling surface positioned below shell 110 or directing low temperature gas toward inner surface 126 of liner 120 to increase the cooling rate of liner 120.

One or more intermediate steps may be inserted between any of the steps of method 400 to improve the adhesion of liner 120 to shell 110. The intermediate steps may include any process or device that improves the adhesion of liner 120 and shell 110.

Higher grade natural or synthetic silica has a high melting point (approximately 1710° C.). As such, a large amount of energy is required to melt synthetic silica and it difficult to soften the silica enough to form a coating using small thermal spraying devices such as thermal spray assembly 300. Thus, source of energy 304 must provide sufficient energy to soften and melt synthetic silica into molten particles.

Additionally, contaminants may be introduced into the molten particles of the coating compound by thermal spray assembly 300 during the thermal spray process. Thermal spray assembly 300 may be designed or configured to reduce or eliminate contaminants introduced into the molten particles of the coating compound by thermal spray assembly 300 during the thermal spray process.

In a flame thermal spray process, providing 406 energy from source of energy 304 generally includes providing chemicals in a vapor state capable of providing energy from an oxidation reaction. That is, flame thermal spray processes generally provide energy and melt the coating compound by burning a hydrocarbon, such as, but not limited, to acetylene, kerosene, or natural gas, in the presence of oxygen or compressed air. Flame thermal spray processes generally include a detonation spray process, a flame wire spray process, a flame powder spray process, a high velocity oxygen fuel (HVOF) spray process, and a high velocity air fuel (HVAF) spray process.

In a detonation spray process, a powered synthetic silica is provided from source of coating compound 306 and injected into a long barrel of spray torch 302. The long barrel is water cooled with water provided from source of cooling medium 310. Oxygen and a hydrocarbon fuel, such as acetylene, are also injected into the barrel and detonated using an ignition mechanism. The detonation melts the powdered synthetic silica and accelerates the molten synthetic silica along with the resulting combustion gases out of the long barrel and onto inner surface 122. The detonation is repeated multiple times per second.

In a flame wire spray process, synthetic silica in the form of a wire is fed into spray torch 302 while oxygen and a hydrocarbon fuel, such as acetylene, are combusted to melt the synthetic silica. Compressed air is also provided to atomize the molten particles of synthetic silica and to accelerate the molten silica toward inner surface 122.

In a flame powder spray process, synthetic silica in the form of a powder is fed into spray torch 302 while oxygen and a hydrocarbon fuel, such as acetylene, are combusted to melt the synthetic silica. Compressed air is mixed with the powdered synthetic silica to transport the silica into the flame. The resultant combustion gases and molten particles of synthetic silica are accelerated toward inner surface 122 by the compressed air.

In a HVOF spray process, spray torch 302 includes a combustion chamber and a nozzle. Oxygen and a hydrocarbon fuel, such as propylene, are fed into the combustion chamber and ignited. The resulting combustion gases are fed through the nozzle to form a supersonic flame which, in turn, is fed into a barrel of spray torch 302 at a high velocity. In some embodiments, the exit velocity of the supersonic flame from the barrel exceeds the speed of sound. Synthetic silica in the form of a powder is entrained in a carrier gas, typically nitrogen, and injected into the barrel of spray torch 302 with the supersonic flame. The supersonic flame melts the synthetic silica into molten particles of synthetic silica and accelerates the molten particles of synthetic silica toward inner surface 122. Cooling water is typically provided to cool spray torch 302.

The HVAF spray process is similar to the HVOF spray process except that compressed air, rather than oxygen, is fed into the combustion chamber and ignited, producing a lower temperature supersonic flame.

In an electrical thermal spray processes, providing energy 406 from source of energy 304 generally includes providing an electrical current that is used to either directly or indirectly melt the synthetic silica. Electrical thermal spray processes generally include a plasma spray process and an arc wire spray process.

In a plasma spray process, spray torch 302 includes an electrode and a nozzle positioned next to each other such that a high frequency or high voltage electric arc is formed therebetween. An inert gas, typically argon, flows between the electrode and the nozzle and is ionized by the electric arc. Ionization of the inert gas creates a plasma with increased temperature and velocity. Synthetic silica in the form of a powder is entrained in the plasma where it is melted into molten particles of synthetic silica and accelerated toward inner surface 122.

In an arc wire spray process, two wires of synthetic silica are fed into spray torch 302 and an electric current is fed to each wire. The wires are brought into close proximity to each other such that the currents in the two wires short circuit, increasing the temperature of the wires. The increased temperature melts the tips of the wires and compressed air or inert gas is channeled past the melting tips of the wires to atomize the molten particles of synthetic silica and accelerate them toward inner surface 122.

In a kinetic thermal spray process, providing energy from source of energy 304 generally includes providing a high velocity atomized gas stream to accelerate the coating compound to very high velocities. Kinetic thermal spray processes generally include variations of a cold gas spray process. In a cold gas spray process, synthetic silica in the form of a powder is entrained in a stream of high velocity atomized gas. The atomized gas is heated and partially melts the synthetic silica. Once entrained, the high velocity atomized gas accelerates the powdered synthetic silica toward inner surface 122 at velocities exceed 1,000 meters per second. The extremely high velocities cause the powdered, partially melted synthetic silica to deform and mechanically bond with inner surface 122 upon impact with inner surface 122, creating liner 120.

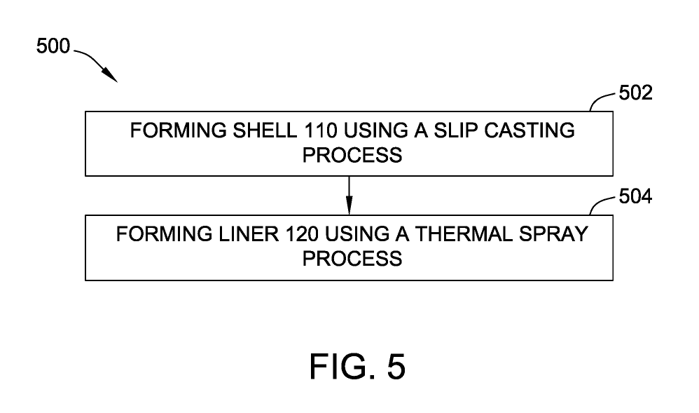

Referring now to FIG. 5, a flow chart illustrates method 500 for making the crucible assembly shown in FIG. 1. The method 500 generally includes forming 502 shell 110 using a slip casting process and forming 504 liner 120 using a thermal spray process. Forming 502 shell 110 using the slip casting process includes forming shell 110 according to method 200 illustrated in FIG. 2. Forming 504 liner 120 using a thermal spray process includes forming liner 120 according to method 400 illustrated in FIG. 4. In alternative embodiments, shell 110 is formed using an alternative process such as gel casting.

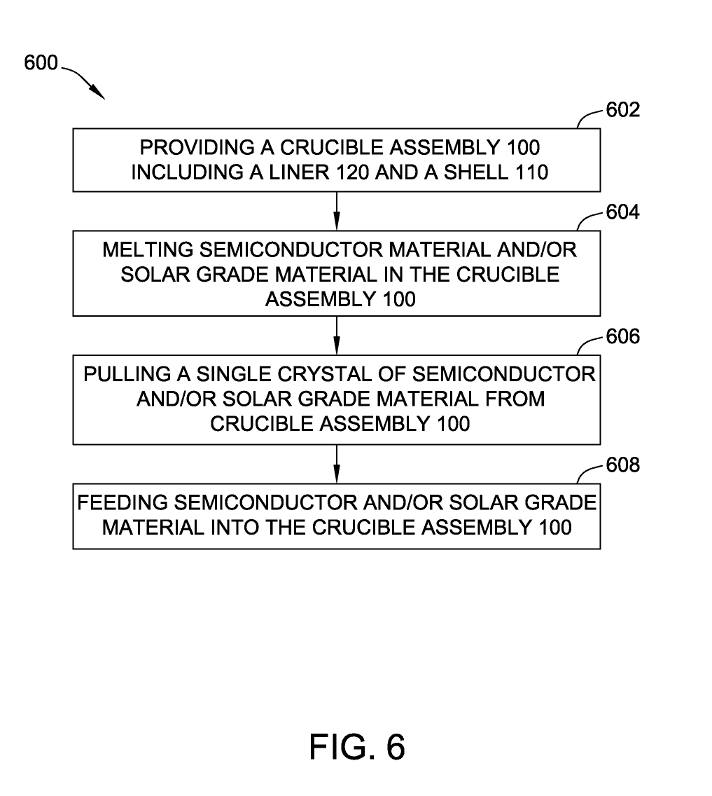

Referring now to FIG. 6, a flow chart illustrates a method 600 for pulling a crystal ingot using the Czochralski method and crucible assembly 100 shown in FIG. 1. Method 600 generally includes providing 602 a crucible assembly 100 including an liner 120 and an shell 110, melting 604 semiconductor material and/or solar grade material in the crucible assembly 100, pulling 606 a single crystal of semiconductor and/or solar grade material from crucible assembly 100, and feeding 608 semiconductor and/or solar grade material into the crucible assembly 100.

The crucible assembly 100 provided for use in method 600 includes liner 120 formed within shell 110 as shown in FIG. 1. Melting 604 semiconductor material and/or solar grade material in crucible assembly 100 includes melting the material in growth region 130. Following melting 604 of the material, molten material at least partially fills growth region 130. Pulling 606 a single crystal of semiconductor and/or solar grade material from crucible assembly 100 includes pulling 606 the single crystal from growth region 130 within liner 120. Feeding 608 semiconductor and/or solar grade material into the crucible assembly 100 includes adding additional material to growth region 130.

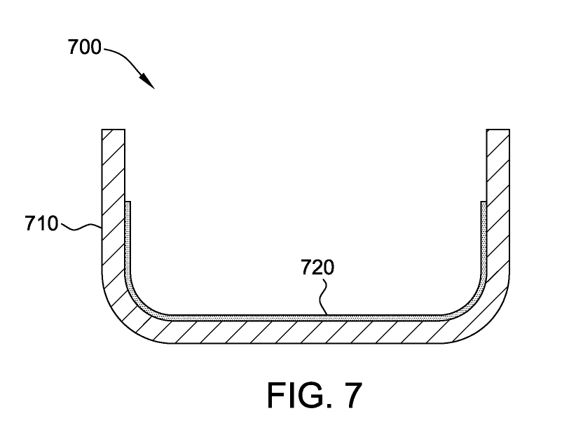

Referring now to FIG. 7, a sectional view of a crucible assembly 700 is illustrated, an alternative embodiment of crucible assembly 100. Crucible assembly 700 includes a liner 720 thermally sprayed on portions of a shell 710. In contrast to crucible assembly 100, liner 720 is only thermally sprayed on the wetted surfaces of crucible assembly 700. Reducing the area of liner 720 reduces the cost of crucible assembly 700 in comparison to crucible assembly 100.

Crucible assemblies made according to this disclosure result in reduced cost, improved design flexibility, improved crucible lifetime, and limited impurities being introduced into a single crystal ingot drawn from the crucible assembly. In some embodiments, crucible assembly reduces cost through the use of a slip cast shell. The reduced cost of slip casting in comparison to arc-fusion, and its use for the larger shell, results in a reduced cost. The cost of producing cast crucibles is less than producing arc-fused crucibles because the capital equipment used in producing cast crucibles is less expensive than that of arc-fused crucibles and the energy required to produce cast crucibles is less than that required for arc-fused crucibles. Additionally, shells made of high impurity, less expensive natural silica rather than lower impurity, higher cost synthetic silica required for manufacture of high quality ingots. Using less expensive materials to form large portions of the crucible substantially reduce the cost.

Crucible assemblies of some embodiments have improved design flexibility because of the use of a cast shell. Molds used to produce cast crucibles can be more easily and more cheaply altered to produce different crucible geometries, e.g., larger or smaller diameter crucibles, in comparison to the equipment used to produce arc-fused crucibles, e.g., rotating molds, electrodes, etc. Finally, liners disclosed herein act as a low impurity barrier between the melt and the high impurity shell. This limits impurities being introduced into a single crystal ingot drawn from crucible assemblies using the liners.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements. The use of terms indicating a particular orientation (e.g., “top”, “bottom”, “side”, “down”, “up”, etc.) is for convenience of description and does not require any particular orientation of the item described.

As various changes could be made in the above constructions and methods without departing from the scope of the invention, it is intended that all matter contained in the above description and shown in the accompanying drawing[s] shall be interpreted as illustrative and not in a limiting sense.

What is claimed is:

1. A method of manufacturing a crucible assembly having a shell and a liner, the method comprising:
forming the shell using a casting process, the shell including silica and having an inner surface and an outer surface;
forming the liner on the inner surface of the shell, the liner formed of synthetic silica.

2. The method claim 1, wherein the casting process is a slip casting process.

3. The method of claim 2, wherein the slip casting process includes:
mixing fused silica, water, a dispersing agent, and a binder to form a slurry;
casting the slurry into a mold;
drying the slurry;
removing the mold from the dried slurry to form a green body; and
firing the green body.

4. The method claim 3, wherein firing the green body includes sintering the green body at high temperature.

5. The method claim 3, wherein the mold includes plaster of Paris.

6. The method claim 3, wherein drying the slurry includes vacuum drying the slurry.

7. The method claim 1, forming the liner on the inner surface of the shell includes forming the liner on the inner surface of the shell by a thermal spray process including spraying synthetic silica on the inner surface of the shell at high temperature.

8. The method of claim 7, wherein the thermal spray process includes:
melting the synthetic silica to form molten particles of the synthetic silica;
accelerating the molten particles of the synthetic silica toward the shell using an acceleration media;
spraying the molten particles of the synthetic silica and the acceleration media toward the inner surface of the shell using a spray torch;
forming a coating of the synthetic silica on the inner surface of the shell; and
bonding the coating of synthetic silica to the shell to form the liner.

9. The method of claim 8 further comprising moving the spray torch in a first direction to form more of the coating.

10. The method of claim 8 further comprising providing a cooling medium to cool the spray torch.

11. The method of claim 8 further comprising providing the acceleration media from a source of acceleration media.

12. The method of claim 8 further comprising providing the synthetic silica in the form of a powdered synthetic silica.

13. The method of claim 8 further comprising providing the synthetic silica in the form of a wire of synthetic silica.

14. The method of claim 8, wherein melting the synthetic silica to form molten particles of the synthetic silica includes melting the synthetic silica with a flame.

15. The method of claim 8, wherein melting the synthetic silica to form molten particles of the synthetic silica includes melting the synthetic silica with an electric current.

16. The method of claim 8, wherein melting the synthetic silica to form molten particles of the synthetic silica includes melting the synthetic silica with an ionized plasma.

17. The method of claim 8, wherein melting the synthetic silica to form molten particles of the synthetic silica includes partially melting the synthetic silica with a heated acceleration media.

18. The method of claim 17, wherein accelerating the molten particles of the synthetic silica toward the shell using an acceleration media includes accelerating the partially melted synthetic silica with the heated acceleration media toward the shell at high velocity.

19. The method of claim 1, wherein the casting process is a gel casting process.

20. A crucible assembly for growing a crystal ingot using a Czochralski process, the assembly comprising:
a shell, the shell formed of silica and having an inner surface and an outer surface opposite the inner surface; and
a liner, the liner formed of synthetic silica and formed on the inner surface of the shell, wherein the liner is a thermal sprayed liner and the shell is a cast shell.
